(19) United States
(12) Patent Application Publication
(10) Pub. No.: US 2026/0237408 A1
(43) Pub. Date: Aug. 13, 2026

(54) MEMORY DEVICE AND MANUFACTURING METHOD OF THE MEMORY DEVICE

(71) Applicant: SK hynix Inc., Icheon-si Gyeonggi-do (KR)

(72) Inventor: Kang Jae LEE, Icheon-si Gyeonggi-do (KR)

(73) Assignee: SK hynix Inc., Icheon-si Gyeonggi-do (KR)

(21) Appl. No.: 19/268,636

(22) Filed: Jul. 14, 2025

(30) Foreign Application Priority Data
Feb. 7, 2025 (KR) 10-2025-0015736

(51) Int. Cl. G11C 5/06; H10B 43/10; H10B 43/40

(52) U.S. Cl. CPC G11C 5/063; H10B 43/10; H10B 43/40

(57) ABSTRACT

A memory device includes a stack including conductive layers and interlayer insulating layers stacked alternately with each other. The memory device also includes cell plugs penetrating through the stack. The memory device further includes a support pattern spaced apart from the stack and the cell plugs, wherein the support pattern includes a through region. The memory device additionally includes contacts penetrating the support pattern through the through region. The support pattern includes openings arranged in a first direction and a second direction in which the support pattern extends.

### CROSS-REFERENCE TO RELATED APPLICATION

The present application claims priority under 35 U.S.C. § 119(a) to Korean patent application number 10-2025-0015736, filed on February 7, 2025, in the Korean Intellectual Property Office, the entire contents of which application is incorporated herein by reference.

### BACKGROUND

### Technical Field

Various embodiments of the present disclosure relate to a memory device and a method of manufacturing the same, and more particularly, to a memory device including a memory block having a three-dimensional structure and a method of manufacturing the same.

### Related Art

A memory device may be a non-volatile memory device that retains stored data even when supplied power is interrupted. The non-volatile memory device may have a two-dimensional structure or a three-dimensional structure, depending on how its memory cells are arranged. Memory cells of a non-volatile memory device having a two-dimensional structure may be arranged in a single layer on a substrate. Memory cells of a non-volatile memory device having a three-dimensional structure may be stacked vertically on a substrate. Because the integration density of a non-volatile memory device having a three-dimensional structure is higher than that of a non-volatile memory device having a two-dimensional structure, the number of electronic devices using non-volatile memory devices having a three-dimensional structure has been increasing in recent years.

### SUMMARY

According to an embodiment, a memory device may include: a stack including conductive layers and interlayer insulating layers stacked alternately with each other; cell plugs penetrating through the stack; a support pattern spaced apart from the stack and the cell plugs, the support pattern including a through region; and contacts penetrating the support pattern through the through region. The support pattern includes openings arranged in a first direction and a second direction in which the support pattern extends.

According to an embodiment, a method of manufacturing a memory device may include: forming a support layer extending in a first direction and a second direction; forming a support pattern including openings arranged in the first direction and the second direction, and forming a through region having a greater width than the openings by removing a portion of the support layer; forming an insulating layer filling the openings and the through region; and forming a contact penetrating the insulating layer and extending through the through region.

### BRIEF DESCRIPTION OF THE DRAWINGS

FIG. 1 is a diagram illustrating a memory device according to an embodiment of the present disclosure;

FIG. 2 is a diagram illustrating a memory device according to an embodiment of the present disclosure;

FIGS. 3A to 3D are diagrams illustrating support patterns included in a memory device according to an embodiment of the present disclosure;

FIGS. 4A to 4E are diagrams illustrating a method of manufacturing a support pattern according to an embodiment of the present disclosure;

FIGS. 5A and 5B are diagrams illustrating various embodiments of a support pattern according to the present disclosure;

FIG. 6 is a diagram illustrating a memory card system to which a memory device of the present disclosure is applied; and

FIG. 7 is a diagram illustrating a solid-state drive (SSD) system to which a memory device of the present disclosure is applied.

### DETAILED DESCRIPTION

Specific structural or functional descriptions of examples of embodiments in accordance with concepts which are disclosed in this specification are illustrated only to describe the examples of embodiments in accordance with the concepts and the examples of embodiments in accordance with the concepts may be carried out by various forms but the descriptions are not limited to the examples of embodiments described in this specification.

Hereinafter, example embodiments of the present disclosure will be described in detail with reference to the accompanying drawings in order for those skilled in the art to be able to readily implement the technical spirit of the present disclosure.

Some embodiments of the present disclosure are directed to a memory device and a method of manufacturing the memory device such that warpage of the memory device is reduced or prevented.

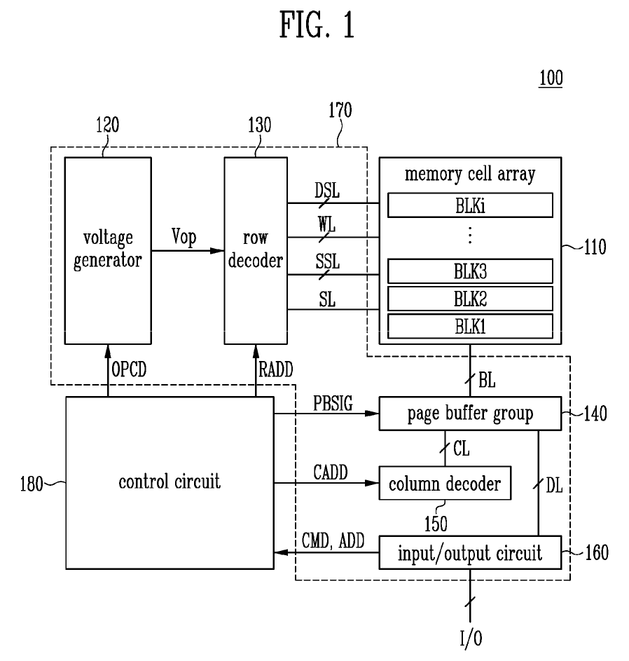

FIG. 1 is a diagram illustrating a memory device 100 according to an embodiment of the present disclosure.

Referring to FIG. 1, the memory device 100 may include a memory cell array 110, a peripheral circuit 170, and a control circuit 180.

The memory cell array 110 may include first to ith memory block BLK1 to BLKi. Each of the first to ith memory blocks BLK1 to BLKi may include memory cells capable of storing data. Drain select lines DSL, word lines WL, source select lines SSL, and a source line SL may be coupled to each of the first to ith memory blocks BLK1 to BLKi. Bit lines BL may be coupled in common to the first to ith memory blocks BLK1 to BLKi.

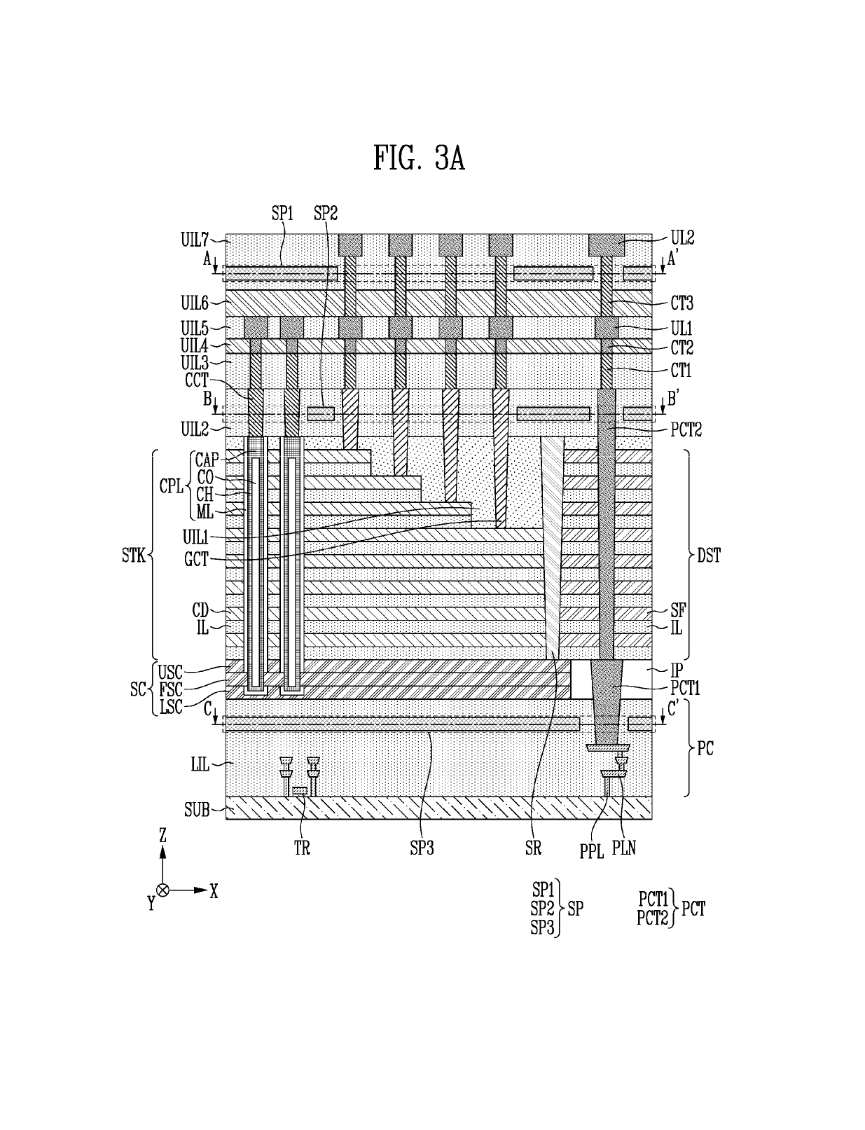

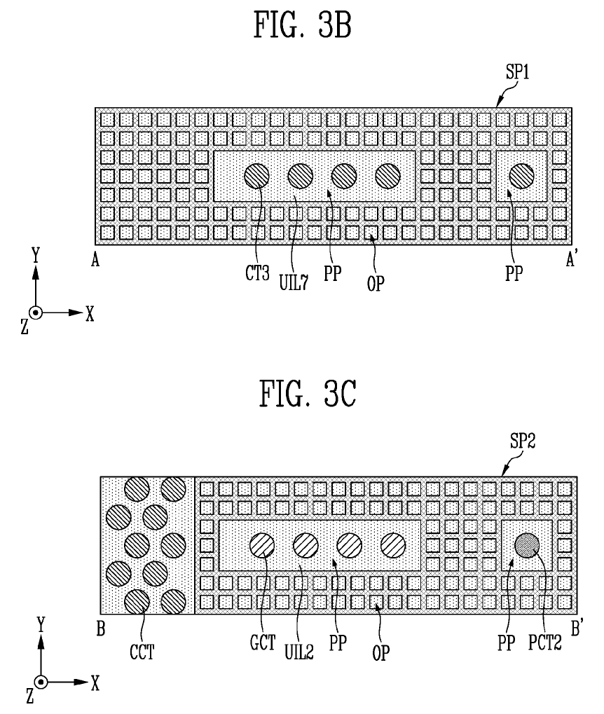

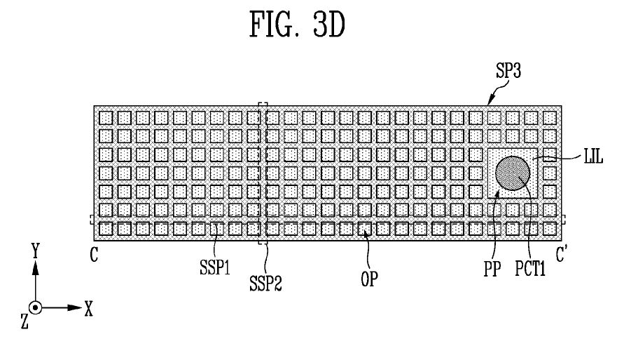

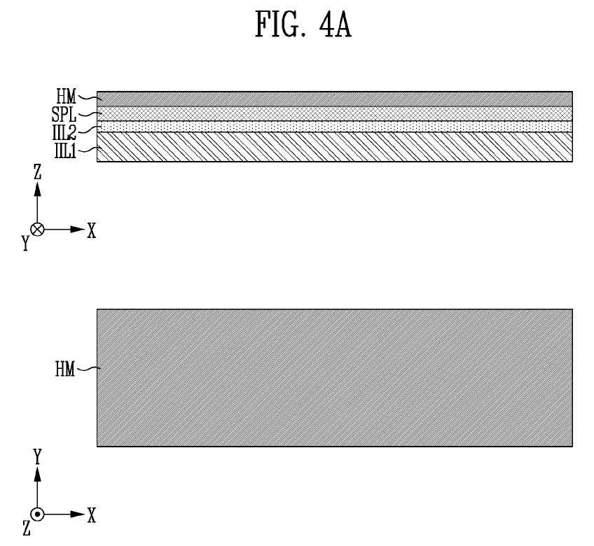

The first to ith memory blocks BLK1 to BLKi may have a three-dimensional structure. Memory blocks having a three-dimensional structure may include memory cells stacked vertically on a substrate. The memory blocks may include a stack including conductive layers and interlayer insulating layers stacked alternately in a vertical direction. Because the stack extends in one direction, warpage of the memory blocks may be induced. However, according to some embodiments of the present disclosure, defects in the memory device 100 may be reduced or prevented by adding support patterns which may reduce or prevent the warpage of the memory blocks. The support patterns are described below with reference to FIG. 3A.

Memory cells may store one bit or two or more bits of data, depending on how the memory cells are programmed. For example, a single memory cell storing one bit of data is referred to as a single-level cell, and a single memory cell storing two bits of data is referred to as a multi-level cell. A single memory cell storing three bits of data is referred to as a triple-level cell, and a single memory cell storing four bits of data is referred to as a quad-level cell. Additionally, five bits of data may be stored in a single memory cell.

The peripheral circuit 170 may perform a program operation to store data in the memory cell array 110, a read operation to output data stored in the memory cell array 110, and an erase operation to erase data stored in the memory cell array 110. For example, the peripheral circuit 170 may include a voltage generator 120, a row decoder 130, a page buffer group 140, a column decoder 150, and an input/output circuit 160.

The voltage generator 120 may generate various operating voltages Vop which are used for a program operation, a read operation, or an erase operation in response to an operation code OPCD. For example, the voltage generator 120 may generate program voltages, turn-on voltages, turn-off voltages, negative voltages, precharge voltages, verify voltages, read voltages, pass voltages, or erase voltages in response to the operation code OPCD. The operating voltages Vop generated by the voltage generator 120 may be applied to the drain select lines DSL, the word lines WL, the source select lines SSL, and the source line SL of the selected memory block through the row decoder 130.

Program voltages may be applied to a selected word line of the word lines WL during a program operation and may be used to increase threshold voltages of the memory cells coupled to the selected word line. Turn-on voltages may be applied to the drain select lines DSL or the source select lines SSL and may be used to turn on drain select transistors or source select transistors. Turn-off voltages may be applied to the drain select lines DSL or the source select lines SSL and may be used to turn off the drain select transistors or the source select transistors. For example, the turn-off voltage may be set to 0 V. Precharge voltages may be higher than 0 V and may be applied to bit lines during a read operation. Verify voltages may be used during a verify operation to determine when the threshold voltage of the selected memory cells have risen to a target level. The verify voltages may be set at various levels depending on the target level and may be applied to selected word lines.

Read voltages may be applied to a selected word line during a read operation of the selected memory cells. For example, the read voltages may be set to various levels depending on how the selected memory cells are programmed. Pass voltages may be applied to unselected word lines of the word lines WL during a program or read operation and may be used to turn on memory cells coupled to unselected word lines. Erase voltages may be used to erase memory cells included in selected memory blocks during an erase operation, and may be applied to the source line SL.

The row decoder 130 may transfer the operating voltages Vop to the drain select lines DSL, the word lines WL, the source select lines SSL, and the source line SL coupled to a selected memory block according to a row address RADD. For example, the row decoder 130 may be coupled to the voltage generator 120 through global lines and coupled to the first to ith memory blocks BLK1 to BLKi through the drain select lines DSL, the word lines WL, the source select lines SSL, and the source line SL.

The page buffer group 140 may include page buffers (not shown) coupled to the first to ith memory blocks BLK1 to BLKi, respectively. Each of the page buffers may be coupled to the first to ith memory blocks BLK1 to BLKi through bit lines BL. During a read operation, the page buffers may sense a current or a voltage on the bit lines which vary according to the threshold voltages of the selected memory cells in response to page buffer control signals PBSIG and may temporarily store the sensed data.

The column decoder 150 may transfer data between the page buffer group 140 and the input/output circuit 160 in response to a column address CADD. For example, the column decoder 150 may be coupled to the page buffer group 140 through column lines CL and transfer enable signals through the column lines CL. The page buffers included in the page buffer group 140 may receive or output data through data lines DL in response to the enable signals.

The input/output circuit 160 may receive or output a command CMD, an address ADD, or data through input/output lines I/O. For example, the input/output circuit 160 may transfer the command CMD and the address ADD received from an external controller to the control circuit 180 through the input/output lines I/O, and may transfer data received from the external controller to the page buffer group 140 through the input/output lines I/O. Alternatively, the input/output circuit 160 may output data received from the page buffer group 140 to the external controller through the input/output lines I/O.

In response to the command CMD and the address ADD, the control circuit 180 may output at least one of the operation code OPCD, the row address RADD, the page buffer control signals PBSIG, and the column address CADD. For example, when the command CMD which is input to the control circuit 180 corresponds to a program operation, the control circuit 180 may control the peripheral circuit 170 to perform the program operation of the memory block selected by the address ADD. When the command CMD which is input to the control circuit 180 corresponds to a read operation, the control circuit 180 may control the peripheral circuit 170 to perform the read operation of the memory block selected by the address ADD and output the read data. When the command CMD which is input to the control circuit 180 corresponds to an erase operation, the control circuit 180 may control the peripheral circuit 170 to perform the erase operation of the selected memory block.

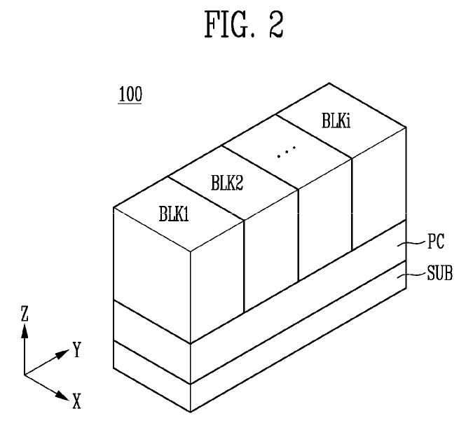

FIG. 2 is a diagram illustrating the memory device 100 according to an embodiment of the present disclosure.

Referring to FIG. 2, the memory device 100 may include a peripheral circuit structure PC arranged on a substrate SUB and the first to ith memory blocks BLK1 to BLKi. The first to ith memory blocks BLK1 to BLKi may overlap with the peripheral circuit structure PC.

The substrate SUB may be a single crystal semiconductor layer. For example, the substrate SUB may be a bulk silicon substrate, a silicon-on-insulator substrate, a germanium substrate, a germanium-on-insulator substrate, a silicon-germanium substrate, or an epitaxial thin layer formed by selective epitaxial growth.

The peripheral circuit structure PC may include the row decoder 130, the column decoder 150, the page buffer group 140, and the control circuit 180, which constitute circuitry for controlling the operations of the first to ith memory blocks BLK1 to BLKi. For example, the peripheral circuit structure PC may include NMOS transistors, PMOS transistors, resistors, and capacitors electrically coupled to the first to ith memory blocks BLK1 to BLKi. The peripheral circuit structure PC may be arranged between the substrate SUB and the first to ith memory blocks BLK1 to BLKi.

Each of the first to ith memory blocks BLK1 to BLKi may include a source structure, bit lines, cell strings electrically coupled to the source structure and the bit lines, word lines electrically coupled to the cell strings, and select lines electrically coupled to the cell strings. Each of the cell strings may include memory cells and select transistors coupled in series by cell plugs. Each of the select lines may serve as a gate electrode of a corresponding select transistor, and each of the word lines may serve as a gate electrode of a corresponding memory cell. The first to ith memory blocks BLK1 to BLKi may be separated from each other by a slit.

Each of the first to ith memory blocks BLK1 to BLKi may extend in the X direction. Therefore, warpage may be induced in the first to ith memory blocks BLK1 to BLKi. However, according to some embodiments of the present disclosure, defects included in the memory device 100 may be reduced or prevented by adding support patterns which may reduce or prevent the warpage of the first to ith memory blocks BLK1 to BLKi. The support patterns are described below with reference to FIG. 3A.

In another embodiment, the substrate SUB, the peripheral circuit structure PC, and the first to ith memory blocks BLK1 to BLKi may be stacked in a reverse order to the order shown in FIG. 2. For example, the peripheral circuit structure PC may be arranged on top of the first to ith memory blocks BLK1 to BLKi.

In another embodiment, unlike the peripheral circuit structure PC shown in FIG. 2, the peripheral circuit structure PC may be arranged on some regions of the substrate SUB which do not overlap the first to ith memory blocks BLK1 to BLKi. For example, the peripheral circuit structure PC and the first to ith memory blocks BLK1 to BLKi may be arranged on non-overlapping regions of the substrate SUB.

FIGS. 3A to 3D are diagrams illustrating support patterns included in a memory device according to an embodiment of the present disclosure. FIG. 3B is a plan view corresponding to the A-A' cross-section of FIG. 3A. FIG. 3C is a plan view corresponding to the B-B' cross-section of FIG. 3A. FIG. 3D is a plan view corresponding to the C-C' cross-section of FIG. 3A.

Referring to FIG. 3A, a memory device (e.g., the memory device 100 of FIGS. 1 and 2, at least one memory block of the first to ith memory blocks BLK1 to BLKi of FIG. 2) may include a stack STK and a dummy stack DST. An isolation structure SR may be located between the stack STK and the dummy stack DST. The dummy stack DST may be spaced apart from the stack STK with the isolation structure SR interposed therebetween.

The stack STK may include conductive layers CD and interlayer insulating layers IL. The conductive layers CD and interlayer insulating layers IL may be alternately stacked in the Z direction. The conductive layers CD may include at least one of tungsten (W), cobalt (Co), nickel (Ni), molybdenum (Mo), silicon (Si), and polysilicon (poly-Si). The interlayer insulating layers IL may include an oxide layer (e.g., silicon oxide). The conductive layers CD may correspond to gate lines (e.g., the drain select line DSL, the word line WL, and the source select line SSL in FIG. 1).

The stack STK may include a stepped structure. The stack STK may include a plurality of steps. Each of the plurality of steps may include a pair including a conductive layer CD and an interlayer insulating layer IL. For example, each of the plurality of steps may include a single conductive layer CD and an interlayer insulating layer IL below the conductive layer CD. In another example, contrary to FIG. 3A, each of the plurality of steps may include a single conductive layer CD and an interlayer insulating layer IL over the conductive layer CD. While FIG. 3A illustrates the steps arranged in the X direction, the shape of the stepped structure is not limited by the illustration of FIG. 3A. For example, the stack STK may include the steps arranged in the Y direction. In another example, the stack STK may include the steps arranged in both X and Y directions. In addition, the steps shown in FIG. 3A are only a portion of the stack STK, and the number of steps may correspond to the number of layers of the conductive layers CD.

The dummy stack DST may include sacrificial layers SF and the interlayer insulating layers IL. The sacrificial layers SF and the interlayer insulating layers IL may be alternately stacked in the Z direction. The sacrificial layers SF may include an insulating material having an etch selectivity with respect to the interlayer insulating layers IL. For example, the interlayer insulating layers IL may include an oxide layer (e.g., a silicon oxide layer), and the sacrificial layers SF may include a nitride layer. The sacrificial layers SF of the dummy stack DST may be located at the same level as the conductive layers CD of the stack STK, respectively. The sacrificial layers SF may be spaced apart from the conductive layers CD with the isolation structure SR interposed therebetween. The interlayer insulating layers IL of the dummy stack DST may be located at the same level as the interlayer insulating layers IL of the stack STK, respectively, and may include the same material.

A first upper insulating layer UIL1 may be disposed on the stack STK and the dummy stack DST. The first upper insulating layer UIL1 may cover the stack STK and the dummy stack DST. The first upper insulating layer UIL1 may cover the stepped structure of the stack STK.

The isolation structure SR may be disposed between the stack STK and the dummy stack DST. The isolation structure SR may separate the dummy stack DST from the stack STK. In one embodiment, a preliminary stack including the sacrificial layers SF and the interlayer insulating layers IL which are stacked alternately with each other may be formed, and some of the sacrificial layers SF may be replaced with the conductive layers CD to form the stack STK. The sacrificial layers SF which are not replaced by the conductive layers CD and remain may constitute the dummy stack DST. For example, while some of the sacrificial layers are removed from the preliminary stack, the sacrificial layers SF corresponding to the dummy stack DST might not be removed by the isolation structure SR. The isolation structure SR may include an insulating material, such as an oxide layer.

A source structure SC may be disposed below the stack STK. The source structure SC may overlap with the stack STK. The source structure SC may extend from the bottom of the stack STK to the bottom of the dummy stack DST. The source structure SC may include an upper source structure USC, an interlayer source structure FSC, and a lower source structure LSC. The interlayer source structure FSC may be located between the upper source structure USC and the lower source structure LSC. The source structure SC may correspond to the source line SL of FIG. 1.

In one embodiment, after the lower source structure LSC, a source sacrificial layer, and the upper source structure USC are stacked sequentially, and cell plugs CPL are formed, the source sacrificial layer may be replaced by the interlayer source structure FSC to form the source structure SC. Through the space where the source sacrificial layer is removed, a portion of a memory layer ML may be etched away to expose the channel layer CH. Thus, the interlayer source structure FSC may directly contact the channel layer CH.

Each of the upper source structure USC, the interlayer source structure FSC, and the lower source structure LSC may include a semiconductor material (e.g., silicon (Si), germanium (Ge), silicon germanium (SiGe), gallium arsenide (GaAs), indium gallium arsenide (InGaAs), aluminum gallium arsenide (AlGaAs), or a mixture thereof). Each of the upper source structure USC, the interlayer source structure FSC, and the lower source structure LSC may include at least one of n-type impurities and p-type impurities. For example, at least one of the upper source structure USC, the interlayer source structure FSC, or the lower source structure LSC may include a polysilicon layer doped with n-type impurities.

An insulation pattern IP may be disposed below the dummy stack DST. The insulation pattern IP may overlap with at least a portion of the dummy stack DST. The insulation pattern IP may penetrate the source structure SC. The insulation pattern IP may be located at the same level as the source structure SC. An upper surface of the insulation pattern IP may be at the same level as an upper surface of the upper source structure USC, and a lower surface of the insulation pattern IP may be at the same level as a lower surface of the lower source structure LSC. The insulation pattern IP may include an insulating material (e.g., oxide or nitride).

The cell plugs CPL may penetrate the stack STK. The cell plugs CPL may abut the source structure SC. The cell plugs CPL may extend through the stack STK and into the source structure SC. The cell plugs CPL may penetrate the upper source structure USC and the interlayer source structure FSC, and may extend into the lower source structure LSC. The memory layer ML may be disposed between the channel layer CH and the upper source structure USC, and between the channel layer CH and the lower source structure LSC. The memory layer ML might not be disposed between the channel layer CH and the interlayer source structure FSC. Thus, the channel layer CH may come into direct contact with the interlayer source structure FSC.

Memory cells and select transistors may be formed at intersections between the cell plugs CPL and the conductive layers CD, respectively. The cell plugs CPL may serve as a channel region of a cell string. For example, drain select transistors, memory cells, and source select transistors may be formed at intersections between the cell plugs CPL and the conductive layers CD, respectively.

The cell plugs CPL may each include the memory layer ML, the channel layer CH, a core pillar CO, and a capping layer CAP. The memory layer ML may have a cylindrical shape. The memory layer ML may contact the stack STK. Though not shown, the memory layer ML may include a blocking layer, a charge trap layer, and a tunnel isolation layer. The blocking layer, the charge trap layer, and the tunnel isolation layer may be sequentially disposed from a side surface of the stack STK. The channel layer CH may be formed along an inner wall of the memory layer. The core pillar CO may have a columnar shape surrounded by the channel layer CH. The capping layer CAP may be coupled to the channel layer CH on the core pillar CO.

The blocking layer and the tunnel isolation layer included in the memory layer ML may include an oxide layer (e.g., a silicon oxide layer) or an oxynitride layer (e.g., a silicon oxynitride layer), or a combination thereof. The charge trap layer included in the memory layer ML may include a nitride layer or a variable resistance material. The channel layer CH and the capping layer CAP may include an undoped or doped silicon layer. The capping layer CAP and the channel layer CH may include the same material or a homogeneous material. Thus, an interface between the capping layer CAP and the channel layer CH might not be present or clearly observed. The core pillar CO may include an insulating or conductive layer.

A second upper insulating layer UIL2 may be disposed over the stack STK and the dummy stack DST. The second upper insulating layer UIL2 may cover the stack STK and the dummy stack DST. The second upper insulating layer UIL2 may overlap with the cell plugs CPL. The second upper insulating layer UIL2 may abut an upper surface of the first upper insulating layer UIL1.

Cell contacts CCT may be formed in the second upper insulating layer UIL2. The cell contacts CCT may penetrate the second upper insulating layer UIL2. The cell contacts CCT may be coupled to cell plugs CPL, respectively. The cell contacts CCT may directly contact the capping layers CAP of the cell plugs CPL. The cell contacts CCT may include a conductive material, such as tungsten.

Gate line contacts GCT may be coupled to the conductive layers CD of the stack STK, respectively. The gate line contacts GCT may be electrically coupled to the conductive layers CD, respectively. The gate line contacts GCT may be in contact with the conductive layers CD, respectively. The gate line contacts GCT may be in contact with steps included in the stack STK, respectively. The gate line contacts GCT may extend in the Z direction from the conductive layers CD. The gate line contacts GCT may penetrate the first upper insulating layer UIL1 and the second upper insulating layer UIL2. Only some of the gate line contacts GCT are shown in FIG. 3A, and the memory block may include a number of gate line contacts GCT corresponding to the number of conductive layers CD that are formed.

The peripheral circuit structure PC and the substrate SUB may be located below the source structure SC and the insulation pattern IP. The peripheral circuit structure PC may be located over the substrate SUB. The peripheral circuit structure PC may include a transistor TR, a peripheral contact plug PPL, and a peripheral line PLN. The transistor TR, the peripheral contact plug PPL, and the peripheral line PLN may have various patterns depending on the configuration of the peripheral circuit PC. For example, the number or arrangement of transistors TR, peripheral contact plugs PPL, and peripheral lines PLN may be varied. A lower insulating layer LIL may be located between the transistor TR, the peripheral contact plug PPL, and the peripheral line PLN. For example, the transistor TR, the peripheral contact plug PPL, and the peripheral line PLN may be formed in the lower insulating layer LIL. The lower insulating layer LIL may include an insulating material, such as an oxide layer.

A peripheral circuit contact PCT may penetrate the dummy stack DST and the insulation pattern IP. The peripheral circuit contact PCT may penetrate the sacrificial layers SF and the interlayer insulating layers IL of the dummy stack DST. The peripheral circuit contact PCT may penetrate the first upper insulating layer UIL1 and the second upper insulating layer UIL2. The peripheral circuit contact PCT may extend into the lower insulating layer LIL to be coupled to the peripheral circuit structure PC. For example, the peripheral circuit contact PCT may contact at least one peripheral line PLN included in the peripheral circuit structure PC.

The peripheral circuit contact PCT may include a first portion PCT1 and a second portion PCT2. The first portion PCT1 may penetrate the insulation pattern IP and extend into the lower insulating layer LIL. The first portion PCT1 may be in direct contact with the peripheral line PLN. The second portion PCT2 may be located on top of the first portion PCT1. The second portion PCT2 may be electrically coupled to the first portion PCT1. The second portion PCT2 may penetrate the dummy stack DST, the first upper insulating layer UIL1, and the second upper insulating layer UIL2. The width of the first portion PCT1 may be greater than the width of the second portion PCT2. The first portion PCT1 and the second portion PCT2 may each include a conductive material.

A third upper insulating layer UIL3, a fourth upper insulating layer UIL4, a fifth upper insulating layer UIL5, a sixth upper insulating layer UIL6, and a seventh upper insulating layer UIL7 may be sequentially stacked over the second upper insulating layer UIL2. The third upper insulating layer UIL3, the fifth upper insulating layer UIL5, and the seventh upper insulating layer UIL7 may include an insulating material, such as an oxide layer. The fourth upper insulating layer UIL4 and the sixth upper insulating layer UIL6 may include an insulating material, such as a nitride layer.

A wiring structure may be formed in the third upper insulating layer UIL3, the fourth upper insulating layer UIL4, the fifth upper insulating layer UIL5, the sixth upper insulating layer UIL6, and the seventh upper insulating layer UIL7. The wiring structure as shown in FIG. 3A is merely one example, and various other arrangements are possible.

The first contacts CT1 may be disposed in the third upper insulating layer UIL3. The first contacts CT1 may penetrate the third upper insulating layer UIL3. The first contacts CT1 may be in contact with the cell contacts CCT, the gate line contacts GCT, and the peripheral circuit contact PCT, respectively. The first contacts CT1 may be electrically coupled to the cell contacts CCT, the gate line contacts GCT, and the peripheral circuit contact PCT, respectively. The first contacts CT1 may include a conductive material.

Second contacts CT2 may be disposed in the fourth upper insulating layer UIL4. The second contacts CT2 may penetrate the fourth upper insulating layer UIL4. The second contacts CT2 may be in contact with the first contacts CT1, respectively. The second contacts CT2 may be electrically coupled to the first contacts CT1, respectively. The second contacts CT2 may include a conductive material.

First upper wires UL1 may be disposed in the fifth upper insulating layer UIL5. The first upper wires UL1 may penetrate the fifth upper insulating layer UIL5. The first upper wires UL1 may be electrically coupled to the second contacts CT2. The first upper wires UL1 may extend in a horizontal direction. For example, the first upper wires UL1 which are electrically coupled to the cell plugs CPL may correspond to bit lines (e.g., the bit line BL in FIG. 1). The first upper wires UL1 may include a conductive material.

Third contacts CT3 may penetrate the sixth upper insulation layer UIL6. The third contacts CT3 may be electrically coupled to the first upper wires UL1. The third contacts CT3 may extend into the seventh upper insulating layer UIL7. Second upper wires UL2 may be electrically coupled to the third contacts CT3. In FIG. 3A, the third contacts CT3 are shown as penetrating the bottom of the seventh upper insulating layer UIL7, not the top thereof. However, the seventh upper insulating layer UIL7 in FIG. 3A may refer to a plurality of layers formed in multiple stages. The third contacts CT3 and the second upper wires UL2 may include a conductive material.

The memory device according to the present disclosure may include support patterns SP. The memory device may include at least one support pattern SP. As shown in FIG. 3A, the memory device may include all three support patterns (SP1, SP2, and SP3), but this is for illustrative purposes only and the number of support patterns SP does not limit the scope of the present disclosure. For example, the memory device may include a first support pattern SP1 and might not include the second and third support patterns SP2 and SP3. In another example, the memory device may include a second support pattern SP2 and might not include the first and third support patterns SP1 and SP3. In yet another example, the memory device may include the second and third support patterns SP2 and SP3 and might not include the first support pattern SP1. Hereinafter, the first to third support patterns SP1 to SP3 which are shown in the same drawing for ease of description will be described.

The support patterns SP may be spaced apart from the stack STK. The support patterns SP may be spaced apart from the stack STK, the dummy stack DST, and the cell plugs CPL. Each of the support patterns SP may be spaced apart from the stack STK in a vertical direction. For example, the first and second support patterns SP1 and SP2 may be located in the Z direction from the stack STK. In addition, the third support pattern SP3 may be located in the opposite direction of the Z direction from the stack STK. The second support pattern SP2 and the third support pattern SP3 may be located at the upper and lower parts of the stack STK, respectively. The first to third support patterns SP1 to SP3 may be spaced apart from each other in the vertical direction. For example, the second support pattern SP2 and the third support pattern SP3 may be spaced apart from each other with the stack STK interposed therebetween.

The support patterns SP may extend in the horizontal direction. The support patterns SP may extend in the X and Y directions. The support patterns SP may have a plate shape extending in the horizontal direction.

The support patterns SP may have a mesh structure. The support patterns SP may have a grid pattern. Referring to FIGS. 3B to 3D, the support patterns SP may include openings OP arranged in the X and Y directions. The openings OP may be disposed continuously in the support patterns SP. For example, in the support patterns SP, the openings OP may be arranged in a continuous manner in all regions except through regions PP. The spacing between the openings OP in the support pattern SP may be constant. The openings OP may be equally spaced in the X direction. In addition, the openings OP may be located at equal intervals in the Y direction. The openings OP may be filled with an insulating layer, such as the lower insulating layer LIL, the second upper insulating layer UIL2, or the seventh upper insulating layer UIL7.

For example, referring to FIG. 3D, the support patterns SP may include first sub-patterns SSP1 extending in the X direction and second sub-patterns SSP2 extending in the Y direction. The first sub-patterns SSP1 may be arranged in the Y direction. The second sub-patterns SSP2 may be arranged in the X direction. The first sub-patterns SSP1 and the second sub-patterns SSP2 may intersect each other. The openings OP may be located at these intersections between the first sub-patterns SSP1 and the second sub-patterns SSP2. In other words, the openings OP may be arranged in the X direction between neighboring first sub-patterns SSP1. Additionally, the openings OP may be arranged in the Y direction between neighboring second sub-patterns SSP2. The openings OP may have a square-shaped plan.

The support patterns SP may include the through region PP. Contacts included in the memory device (e.g., the cell contacts CCT, the gate line contacts GCT, and the peripheral circuit contact PCT) may penetrate the support patterns SP through the through regions PP. For example, the contacts may pass through the through regions PP. The through regions PP may be filled with insulating layers (e.g., the lower insulating layer LIL, the second upper insulating layer UIL2, and the seventh upper insulating layer UIL7). These contacts may be spaced apart from the support patterns SP by the insulating layers.

The first support pattern SP1 may be formed in the seventh upper insulating layer UIL7. The first support pattern SP1 may be located between portions of the wiring structure over the stack STK. The first support pattern SP1 may extend through the wiring structure. Referring to FIGS. 3A and 3B, the first support pattern SP1 may include the through regions PP corresponding to locations of the third contacts CT3. For example, the first support pattern SP1 may include two through regions PP. The first support pattern SP1 may include the through region PP that the third contacts CT3 coupled to the gate line contacts GCT penetrate. The first support pattern SP1 may also include the through region PP that the third contacts CT3 coupled to the peripheral circuit contact PCT penetrate. The through regions PP may be filled with the seventh upper insulating layer UIL7. The third contacts CT3 may be surrounded by the seventh upper insulating layer UIL7. The third contacts CT3 may be spaced apart from the first support pattern SP1 by the seventh upper insulating layer UIL7. The third contacts CT3 may penetrate the first support pattern SP1 through the through regions PP.

The second support pattern SP2 may be formed in the second upper insulating layer UIL2. The second support pattern SP2 may be located over the stack STK. The second support pattern SP2 may extend between portions of the wiring structure coupled to the stack STK. Referring to FIGS. 3A and 3C, the second support pattern SP2 may include the through regions PP corresponding to locations of the cell contacts CCT, the gate line contacts GCT, and the peripheral circuit contact PCT. For example, the second support pattern SP2 may include three through regions PP. The second support pattern SP2 may include the through region PP that the cell contacts CCT penetrate, the through region PP that the gate line contacts GCT penetrate, and the through region PP that the second portion PCT2 of the peripheral circuit contact PCT penetrates. The through regions PP may be filled with the second upper insulating layer UIL2. The cell contacts CCT, the gate line contacts GCT, and the second portion PCT2 of the peripheral circuit contact PCT may contact the second upper insulating layer UIL2. The cell contacts CCT, the gate line contacts GCT, and the second portion PCT2 of the peripheral circuit contact PCT may be spaced apart from the second support pattern SP2 by the second upper insulating layer UIL2. The cell contacts CCT, the gate line contacts GCT, and the second portion PCT2 of the peripheral circuit contact PCT may extend into the through regions PP. The cell contacts CCT, the gate line contacts GCT, and the second portion PCT2 of the peripheral circuit contact PC may penetrate the second support pattern SP2 through the through regions PP.

The third support pattern SP3 may be formed in the lower insulating layer LIL. The third support pattern SP3 may be located below the stack STK. The third support pattern SP3 may be located in the peripheral circuit structure PC. Referring to FIGS. 3A and 3D, the third support pattern SP3 may include the through region PP corresponding to the location of the peripheral circuit contact PCT. For example, the third support pattern SP3 may include the through region PP that the first portion PCT1 of the peripheral circuit contact PCT penetrates. The through region PP may be filled with the lower insulating layer LIL. The first portion PCT1 of the peripheral circuit contact PCT may contact the lower insulating layer LIL. The first portion PCT1 of the peripheral circuit contact PCT may be spaced from the third support pattern SP3 by the lower insulating layer LIL. The first portion PCT1 of the peripheral circuit contact PCT may extend into the through region PP. The first portion PCT1 of the peripheral circuit contact PCT may penetrate the third support pattern SP3 through the through region PP.

The support patterns SP may have a higher stiffness than the interlayer insulating layer IL. In addition, the support patterns SP may also have a higher stiffness than the first to seventh upper insulating layers UIL1 to UIL7 or the isolation structure SR. For example, the support patterns SP may include one or more of silicon carbide (SiC), aluminum oxide (Al₂O₃), boron nitride (BN), tungsten carbide (WC), tungsten (W), iron (Fe), and copper (Cu). As used herein, the term ‘stiffness’ may refer to the property of a layer to maintain its shape without deforming even when stress is applied to the layer. When a material is subjected to stress, the greater the maximum stress at which the material may maintain its shape without deforming, the stiffer the material is considered to be. For example, the oxide layer (e.g., the silicon oxide layer) included in the first to seventh upper insulating layers UIL1 to UIL7 or the isolation structure SR may retain the shape until 70 to 75 gigapascals (GPa) is applied. Silicon carbide, which may be included in the support patterns SP, may retain the existing shape up to 450 GPa, aluminum oxide up to 370 GPa, boron nitride up to 360 GPa, tungsten carbide up to 500 to 700 GPa, tungsten up to 400 GPa, iron up to 211 GPa, and copper up to 130 GPa. Therefore, the stiffness of the support patterns SP may be higher than the first to seventh upper insulating layers UIL1 to UIL7 or the isolation structure SR.

According to some embodiments, the warpage of the memory device may be reduced or prevented by the support patterns SP with high stiffness. The stiffness of the memory device may be increased by the support patterns SP which extend in the X and Y directions. The support patterns SP may have a mesh shape in all but some of the regions where the contacts are formed, thereby improving the in-plane stiffness of the memory device. Thus, the memory device including at least one support pattern SP according to the present disclosure may include no or fewer defects (e.g., cracks) which occur when the memory device is bent.

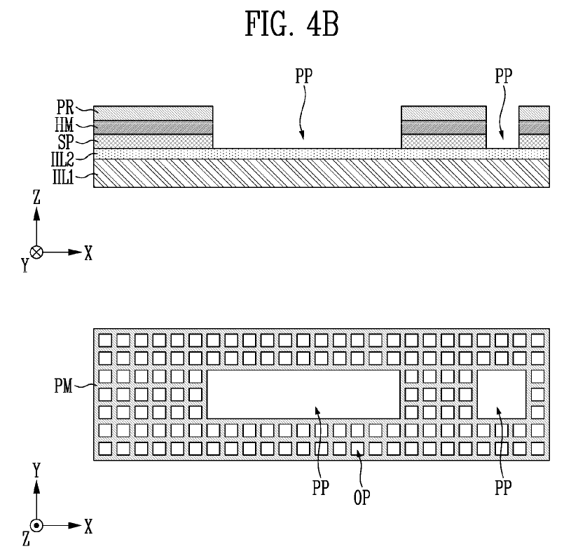

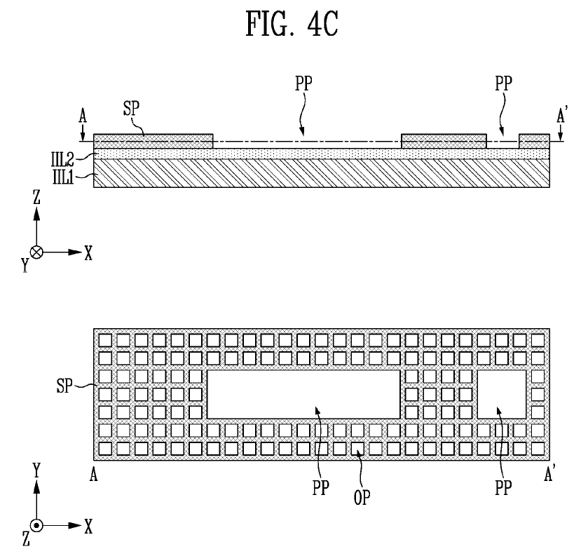

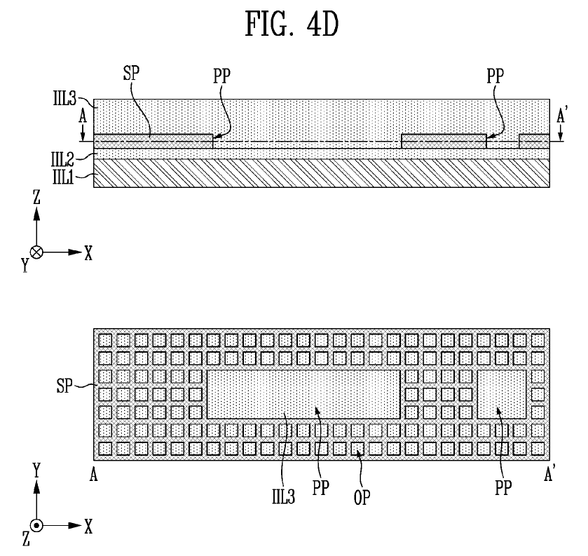

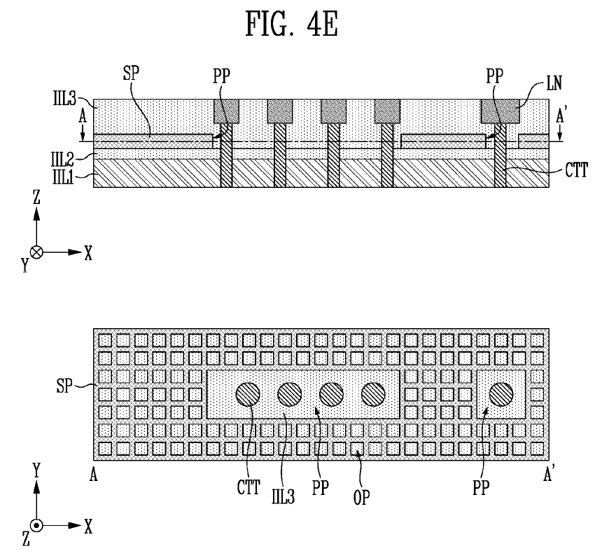

FIGS. 4A to 4E are diagrams illustrating a method of manufacturing a support pattern SP according to an embodiment of the present disclosure.

FIGS. 4A to 4E illustrate a method of manufacturing the support pattern SP. The following description may be adapted and applied to the first to third support patterns SP1 to SP3 shown in FIG. 3A. For ease of explanation, one support pattern SP having a similar shape to the first support pattern SP1 is described mainly.

Referring to FIG. 4A, a support layer SPL may be formed on a first insulating layer IIL1 and a second insulating layer IIL2. The support layer SPL may cover the first and second insulating layers IIL1 and IIL2. The support layer SPL may extend in a horizontal direction (e.g., the X direction and the Y direction). The support layer SPL may have a higher stiffness than the first and second insulating layers IIL1 and IIL2. For example, the first insulating layer IIL1 may include a nitride layer and the second insulating layer IIL2 may include an oxide layer. The support layer SPL may include one or more of of silicon carbide (SiC), aluminum oxide (Al₂O₃), boron nitride (BN), tungsten carbide (WC), tungsten (W), iron (Fe), and copper (Cu).

Subsequently, a hard mask HM may be formed on the support layer SPL. The hard mask HM may cover the support layer SPL. The hard mask HM may contact an upper surface of the support layer SPL. The hard mask HM may include a nitride material.

Referring to FIG. 4B, a photoresist layer may be formed on the hard mask HM. The photoresist layer may cover the hard mask HM. The photoresist layer may include a material whose chemical properties are changed by light.

Subsequently, a portion of the photoresist layer may be removed to form a photoresist PR. For example, a mask including a light-transmitting region and a light-shielding region may be aligned on the photoresist layer. Light may be applied to the photoresist layer by using the mask. In the photoresist layer, exposed and non-exposed regions may have different characteristics. Depending on the type of the photoresist layer, the exposed region may be removed and the non-exposed region may remain, or the non-exposed region may be removed and the exposed region may remain. The residual portion of the photoresist layer may be referred to as the photoresist PR. The photoresist PR may include an opening region corresponding to the region from which the photoresist layer is removed.

Subsequently, the hard mask HM and the support layer SPL may be etched using the photoresist PR. By using the opening region included in the photoresist PR, a portion of the hard mask HM may be removed and a portion of the support layer SPL may be removed. A portion of the support layer SPL may be removed to form the support pattern SP.

The support pattern SP may include the openings OP arranged in the X and Y directions. The openings OP may be arranged continuously in the support pattern SP. For example, in the support patterns SP, the openings OP may be arranged in a continuous manner in all regions except the through regions PP. The spacing between the openings OP in the support pattern SP may be constant. The openings OP may be equally spaced in the X direction. The openings OP may be equally spaced in the Y direction.

The support pattern SP may have a mesh structure. The support patterns SP may have a lattice shape. For example, as shown with reference to FIG. 3D, the support patterns SP may include the first sub-patterns SSP1 extending in the X direction and the second sub-patterns SSP2 extending in the Y direction. The openings OP may be located between the first sub-patterns SSP1 and the second sub-patterns SSP2.

The support pattern SP may include the through regions PP. Each of the through regions PP may have a greater area than each of the openings OP. The through regions PP may be surrounded by the openings OP. The locations of the through regions PP may be determined by locations where contacts are formed.

In one embodiment, the through regions PP and the openings OP may be formed simultaneously. In another embodiment, the through regions PP and the openings OP might not be formed at the same time. For example, the openings OP may be formed first and the through regions PP may then be formed using a separate photoresist. In another example, the through regions PP may be formed first and the openings OP may then be formed using a separate photoresist.

Referring to FIG. 4C, the photoresist PR and the hard mask HM may be removed.

Referring to FIG. 4D, a third insulating layer IIL3 covering the support pattern SP may be formed. The third insulating layer IIL3 may fill the openings OP and the through regions PP of the support pattern SP. The third insulating layer IIL3 may include a material equivalent to the second insulating layer IIL2. The interface between the second insulating layer IIL2 and the third insulating layer IIL3 might not be present or clearly observed.

Referring to FIG. 4E, contacts CTT extending into the through regions PP may be formed. The contacts CTT may penetrate the first insulating layer IIL1 and the second insulating layer IIL2. The contacts CTT may penetrate portions of the third insulating layer IIL3 which fill the through regions PP. The contacts CTT may include the third contacts CT3, the cell contacts CCT, the gate line contacts GCT, or the peripheral circuit contact PCT of FIG. 3A. In addition, wires LN may be formed over the contacts CTT. The wires LN may contact upper surfaces of the contacts CTT. The contacts CTT and the wires LN may be formed at the same time, or the wires LN may be formed after the contacts CTT are formed. The wires LN may be surrounded by the third insulating layer IIL3.

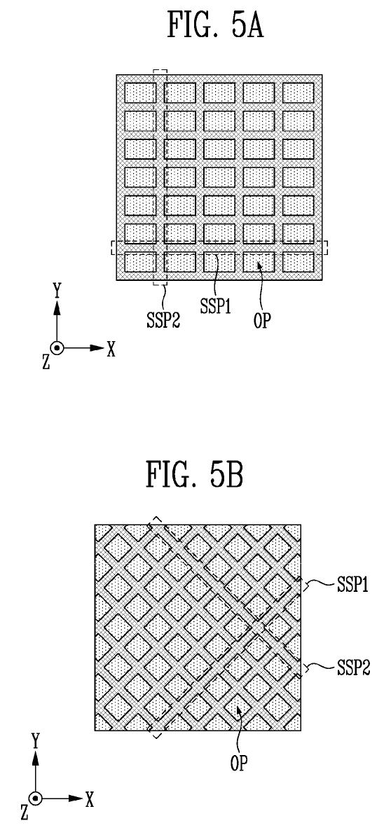

The mesh structure of the support patterns SP as shown in FIGS. 3B to 3D and FIGS. 4A to 4E is illustrative and does not limit the scope of the present disclosure. Various forms of the mesh structure of the support patterns SP are described below with reference to FIGS. 5A and 5B.

FIGS. 5A and 5B are diagrams illustrating various embodiments of the support patterns SP according to the present disclosure.

Referring to FIG. 5A, the openings OP may have different widths in the X direction and the Y direction. The openings OP may have a rectangular planar shape. The spacing between the second sub-patterns SSP2 may be greater than the spacing between the first sub-patterns SSP1.

Referring to FIG. 5B, the directions in which the openings OP are arranged might not be the X and Y directions. For example, the openings OP may be arranged in a first direction and a second direction, the first direction may be between the X and Y directions, and the second direction may be between the Y and X directions opposite the X direction. The first sub-patterns SSP1 may extend in the first direction, and the second sub-patterns SSP2 may extend in the second direction.

FIGS. 5A and 5B correspond to some examples of the structure of the support patterns SP. The support patterns SP may have various other shapes. For example, the openings OP may have a rectangular shape and be arranged in the first direction and the second direction. In another example, the openings OP may have a rhombic, circular, or elliptical shape, rather than a square or rectangular shape. In another example, the openings OP may have different areas, the spacing between the openings OP might not be uniform, or they may be formed in only a portion of the entire area of the support pattern SP.

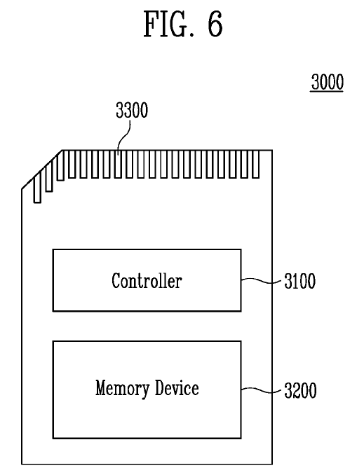

FIG. 6 is a block diagram illustrating a memory card system 3000 according to an embodiment of the present disclosure.

Referring to FIG. 6, the memory card system 3000 may include a controller 3100, a memory device 3200, and a connector 3300.

The controller 3100 may be coupled to the memory device 3200. The controller 3100 may access the memory device 3200. For example, the controller 3100 may control a program, read, or erase operation, or a background operation of the memory device 3200. The controller 3100 may be configured to provide an interface between the memory device 3200 and a host. The controller 3100 may be configured to drive firmware for controlling the memory device 3200. For example, the controller 3100 may include components, such as Random-Access Memory (RAM), a processing unit, a host interface, a memory interface, and an ECC circuit.

The controller 3100 may communicate with an external device through the connector 3300. The controller 3100 may communicate with an external device (e.g., a host) based on a specific communication protocol. For example, the controller 3100 may communicate with the external device through at least one of various communication protocols, such as universal serial bus (USB), multimedia card (MMC), embedded MMC (eMMC), peripheral component interconnection (PCI), PCI-express (PCI-E), advanced technology attachment (ATA), serial-ATA (SATA), parallel-ATA (PATA), small computer system interface (SCSI), enhanced small disk interface (ESDI), integrated drive electronics (IDE), Firewire, universal flash storage (UFS), WiFi, Bluetooth, and non-volatile memory express (NVMe) protocols. In an embodiment, the connector 3300 may be defined by at least one of the above-described various communication protocols.

The memory device 3200 may include a plurality of memory cells and be configured in the same manner as the memory device 100 shown in FIG. 1.

The controller 3100 and the memory device 3200 may be integrated into a single semiconductor device to form a memory card. For example, the controller 3100 and the memory device 3200 may be integrated into a single semiconductor device to form a memory card, such as a personal computer memory card international association (PCMCIA) card, a compact flash (CF) card, a smart media card (SM, or SMC), a memory stick, a multimedia card (MMC, RS-MMC, MMCmicro, or eMMC), an SD card (SD, miniSD, microSD, or SDHC), a universal flash storage (UFS), and the like.

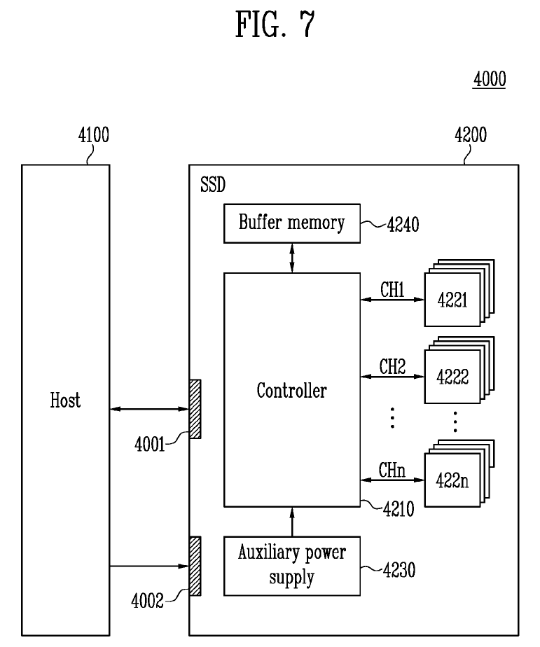

FIG. 7 is a block diagram illustrating a solid-state drive (SSD) system 4000 to which a memory device according to an embodiment of the present disclosure is applied.

Referring to FIG. 7, the SSD system 4000 may include a host 4100 and an SSD 4200. The SSD 4200 may exchange signals with the host 4100 through a signal connector 4001 and may receive power through a power connector 4002. The SSD 4200 may include a controller 4210, a plurality of memory devices 4221 to 422n, an auxiliary power supply 4230, and a buffer memory 4240.

The controller 4210 may control the plurality of memory devices 4221 to 422n in response to the signals received from the host 4100. In an embodiment, the signals may be based on the interfaces of the host 4100 and the SSD 4200. For example, the signals may be defined by at least one of various interfaces, such as universal serial bus (USB), multimedia card (MMC), embedded MMC (eMMC), peripheral component interconnection (PCI), PCI-express (PCI-E), advanced technology attachment (ATA), serial-ATA (SATA), parallel-ATA (PATA), small computer system interface (SCSI), enhanced small disk interface (ESDI), integrated drive electronics (IDE), Firewire, universal flash storage (UFS), WiFi, Bluetooth, and non-volatile memory express (NVMe) interfaces.

The plurality of memory devices 4221 to 422n may include a plurality of memory cells which are configured to store data. Each of the plurality of memory devices 4221 to 422n may be configured in the same manner as the memory device 100 shown in FIG. 1. The plurality of memory devices 4221 to 422n may communicate with the controller 4210 through channels CH1 to CHn.

The auxiliary power supply 4230 may be coupled to the host 4100 through the power connector 4002. The auxiliary power supply 4230 may be supplied and charged with the power from the host 4100. The auxiliary power supply 4230 may supply the power of the SSD 4200 when the power is not smoothly supplied from the host 4100. In an embodiment, the auxiliary power supply 4230 may be positioned inside or outside the SSD 4200. For example, the auxiliary power supply 4230 may be disposed in a main board and supply auxiliary power to the SSD 4200.

The buffer memory 4240 may serve as a buffer memory of the SSD 4200. For example, the buffer memory 4240 may store data received from the host 4100 or data received from the plurality of memory devices 4221 to 422n, or may store metadata (e.g., mapping tables) of the memory devices 4221 to 422n. The buffer memory 4240 may include volatile memories such as DRAM, SDRAM, DDR SDRAM, and LPDDR SDRAM, or non-volatile memories such as FRAM, ReRAM, STT-MRAM, and PRAM.

According to some embodiments of the present disclosure, warpage of a memory device may be reduced or prevented by adding structural configurations.

It will be apparent to those skilled in the art that various modifications can be made to the above-described embodiments of the present disclosure without departing from the spirit or scope of the invention. Thus, it is intended that the present invention cover all such modifications provided they come within the scope of the appended claims and their equivalents.

What is claimed is:

1. A memory device, comprising:
a stack including conductive layers and interlayer insulating layers stacked alternately with each other;
cell plugs penetrating through the stack;
a support pattern spaced apart from the stack and the cell plugs, the support pattern including a through region; and
contacts penetrating the support pattern through the through region,
wherein the support pattern includes openings arranged in a first direction and a second direction in which the support pattern extends.

2. The memory device of claim 1, wherein the support pattern has a higher stiffness than the interlayer insulating layers.

3. The memory device of claim 1, wherein the support pattern comprises at least one of silicon carbide (SiC), aluminum oxide (Al₂O₃), boron nitride (BN), tungsten carbide (WC), tungsten (W), iron (Fe), and copper (Cu).

4. The memory device of claim 1, wherein the support pattern is spaced apart from the stack in a direction in which the conductive layers and the interlayer insulating layers are alternately stacked.

5. The memory device of claim 1, wherein the direction in which the conductive layers and the interlayer insulating layers are alternately stacked is normal to a plane defined by the first direction and the second direction in which the support pattern extends.

6. The memory device of claim 1, wherein the support pattern comprises a mesh structure.

7. The memory device of claim 1, wherein the support pattern comprises:
first sub-patterns extending in the first direction; and
second sub-patterns extending in the second direction, and
wherein each of the openings is located at an intersection between a first sub-pattern of the first sub-patterns and a second sub-pattern of the second sub-patterns.

8. The memory device of claim 1, wherein the openings are arranged continuously in the support pattern except for the through region of the support pattern.

9. The memory device of claim 1, wherein the openings are spaced at regular intervals in the support pattern.

10. The memory device of claim 1 further comprising:
a first insulating layer filling the through region; and
a second insulating layer filling the openings.

11. The memory device of claim 10, wherein the contacts penetrate the first insulating layer and are separated from the support pattern by the first insulating layer.

12. The memory device of claim 1 further comprising a peripheral circuit structure located below the stack,
wherein the support pattern is located in the peripheral circuit structure.

13. The memory device of claim 1 further comprising a dummy stack located in the first direction of the stack,
wherein the contacts include a peripheral circuit contact penetrating through the dummy stack, and
wherein the peripheral circuit contact extends through the through region of the support pattern.

14. The memory device of claim 1 further comprising a first upper insulating layer disposed over the stack,
wherein the support pattern is located in the first upper insulating layer.

15. The memory device of claim 14, wherein the contacts comprise cell contacts penetrating the first upper insulating layer and coupled to the cell plugs, respectively, and
wherein the cell contacts extend through the through region of the support pattern.

16. The memory device of claim 1, wherein the contacts comprise gate line contacts coupled to the conductive layers, respectively, and
wherein the gate line contacts extend through the through region of the support pattern.

17. The memory device of claim 1 further comprising a wiring structure arranged over the stack,
wherein the support pattern extends through the wiring structure.
